(19) United States
(12) Patent Application Publication
(10) Pub. No.: US 2007/0063214 A1
(43) Pub. Date: Mar. 22, 2007

(54) Light emitting diode package and method for manufacturing the same

(75) Inventors: Yong Sik Kim, Yongin (KR); Seog Moon Choi, Seoul (KR); Chang Hyun Lim, Suwon (KR); Yong Suk Kim, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/524,278

(22) Filed: Sep. 21, 2006

(30) Foreign Application Priority Data
Sep. 22, 2005 (KR) 10-2005-0088338

(51) Int. Cl. H01L 33/00

(52) U.S. Cl. 257/99

(57) ABSTRACT

The invention relates to a light emitting diode package that can prevent deterioration of phosphor and a method of manufacturing the same. The light emitting diode package includes a package body having a recessed part, a light emitting diode chip mounted on a floor surface of the recessed part and a lens structure disposed on an upper surface of the package body, apart from the light emitting diode chip. Phosphor is dispersed in at least a part of the lens structure.

### CLAIM OF PRIORITY

This application claims the benefit of Korean Patent Application No. 2005-88338 filed on Sep. 22, 2005, in the Korean Intellectual Property Office, the disclosure of which is incorporated herein by reference.

### BACKGROUND OF THE INVENTION

1. Field of the Invention

The present invention relates to a light emitting diode package and a method for manufacturing the same, and more particularly, to a light emitting diode package that can prevent deterioration of phosphors, thereby having high light extraction efficiency, and a method for manufacturing the same.

2. Description of the Related Art

Recently, light emitting diodes (hereinafter, referred to as ‘LED’) are used as light sources of various colors. In particular, with an increasing demand for high-output, high-luminance LEDs such as white LEDs for illumination, there have been active researches conducted on methods for enhancing the capacity and reliability of LED packages. In general, superior performance of an LED product is ensured by an LED chip having high light efficiency, and an LED package which has efficient light extraction capability and superior color purity and is less susceptible to deterioration by heat.

In general, a white LED package can be manufactured using an appropriate LED chip and phosphor. For example, a blue LED chip mounted on a package body can be encapsulated by a resin with yellow phosphor dispersed therein to obtain a white LED package. For example, when light having a wavelength of 460 nm is generated from the blue LED chip, light having a wavelength of 545 nm is generated from the yellow phosphor in the resin. Thus, the lights of the two wavelengths are mixed to output white light. To increase light extraction efficiency and adjust the beam angle of emitted light, a lens may be mounted on an upper part of the LED package.

FIG. 1 is a sectional view illustrating a conventional LED package 10. Referring to FIG. 1, the LED package 10 includes a package body 11 and an LED chip 17. The package body 11 has a recessed part formed for mounting the LED chip, and a sidewall surface of the recessed part forms a reflecting surface 15. And lead electrodes 13 and 14 are disposed on a floor surface of the recessed part and electrically connected to the LED chip 17 mounted in the package. The mounted LED chip 17 is encapsulated by a resin 19 made of epoxy resin or silicone resin, and a lens 18 is adhered to an upper surface of the package body 11.

To obtain a desired wavelength of output light such as white light, phosphor particles for wavelength conversion are dispersed in the resin 19. For example, yellow phosphor YAG:Ce can be dispersed in the silicone resin. According to such a conventional LED package 10, as the LED chip 17 is in direct contact with the resin, the heat generated from the LED chip 17 is directly transferred to the resin, thereby easily deteriorating the resin and the phosphor. This may not allow obtainment of the desired wavelength of light. As a matter of fact, the resin has very low conductivity of 0.2˜1 W/m·K, and thus the heat generated from the LED chip is not easily discharged, deteriorating the phosphor dispersed in the resin. Thus, with deterioration of the heat characteristics of the phosphor-containing resin, light extraction efficiency is lowered and uniform light emission is hindered.

### SUMMARY OF THE INVENTION

The present invention has been made to solve the foregoing problems of the prior art and therefore an object of certain embodiments of the present invention is to provide a light emitting diode package which prevents deterioration of phosphor, thereby having high light extraction efficiency and uniform light emission characteristics.

Another object of certain embodiments of the invention is to provide a method for manufacturing a light emitting diode package which prevents deterioration of phosphors, thereby achieving high light extraction efficiency and uniform light emission characteristics.

According to an aspect of the invention for realizing the object, there is provided a light emitting diode package including: a package body having a recessed part; a light emitting diode chip mounted on a floor surface of the recessed part; and a lens structure disposed apart from the light emitting diode chip and above the package body, the lens structure containing a phosphor dispersed in at least a part thereof.

According to an embodiment of the invention, the light emitting diode chip may be a blue light emitting diode chip, and the phosphor may be yellow phosphor. By including the yellow phosphor and the blue LED chip in the package, a white light emitting diode that is less susceptible to deterioration of phosphor and has superior light emission characteristics is realized.

According to a preferred embodiment of the invention, the lens structure comprises a lens and a resin film formed on a bottom surface of the lens, the resin film containing the phosphor. In the resin film, phosphor is dispersed to convert the wavelength.

According to another embodiment of the invention, the lens structure may include a lens containing the phosphor dispersed therein. In this case, the lens does not need to have a resin film containing phosphor on a bottom surface thereof. Preferably, the phosphor is dispersed throughout an entire area of the lens.

According to the present invention, the light emitting diode package may further include a light-transmitting resin molded between the lens structure and the light emitting diode chip to encapsulate the light emitting diode chip. In this case, the light-transmitting resin may be, for example, a silicone resin or epoxy resin.

According to another aspect of the invention for realizing the object, there is provided a method of manufacturing a light emitting diode package, including steps of:

mounting a light emitting diode chip on a floor surface of a recessed part of a package body;

preparing a lens structure containing phosphor dispersed in at least a part thereof; and

attaching the lens structure on an upper surface of the package body, apart from the light emitting diode chip. The method may further include encapsulating the light emitting diode chip with light-transmitting resin after the mounting step.

According to a preferred embodiment of the invention, the preparing step may include fabricating a lens and forming a phosphor-containing resin film on a bottom surface of the lens. In this case, the step of forming the phosphor-containing resin film may include spin-coating a resin with the phosphor dispersed therein on a bottom surface of the lens. As an alternative, the step of forming the phosphor-containing resin film may include bonding a resin film with the phosphor dispersed therein on a bottom surface of the lens.

According to another embodiment of the invention, the step of preparing the lens structure may include dispersing the phosphor in a lens material and forming a lens using the lens material. In this case, the phosphor is preferably dispersed throughout an entire area of the lens.

According to the present invention, the phosphor for wavelength conversion is disposed in the lens structure, apart from the LED chip. Thus, deterioration of the phosphor by the heat discharged from the LED chip and degradation of light extraction efficiency can be prevented. In addition, the phosphor is dispersed in the resin film or in the lens, apart from the LED chip to thereby decrease the difference between the paths of light passing through the phosphor, resulting in enhanced uniform light emission characteristics.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view illustrating a conventional light emitting diode package;

FIG. 2 is a sectional view illustrating a light emitting diode package according to an embodiment of the present invention;

FIG. 3 is a sectional view illustrating a light emitting diode package according to another embodiment of the present invention;

FIGS. 4 to 7 are sectional views illustrating manufacturing steps of a light emitting diode package according to an embodiment of the present invention; and

FIGS. 8 and 9 are sectional views illustrating manufacturing steps of a light emitting diode package according to another embodiment of the present invention.

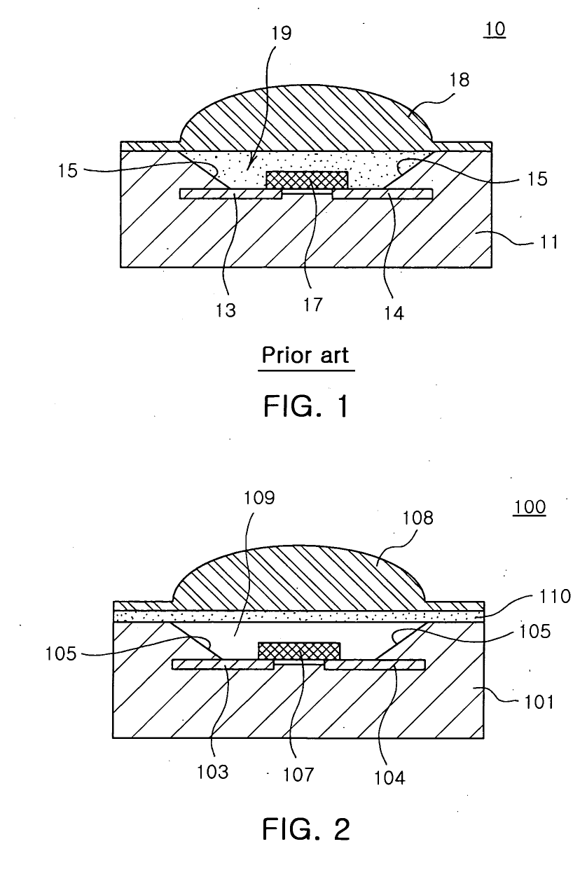

### DETAILED DESCRIPTION OF THE PREFERRED EMBODIMENT

The present invention now will be described more fully hereinafter with reference to the accompanying drawings, in which preferred embodiments of the invention are shown. This invention may, however, be embodied in many different forms and should not be construed as limited to the embodiments set forth herein. Rather these embodiments are provided so that this disclosure will be thorough and complete, and will fully convey the scope of the invention to those skilled in the art. In the drawings, the shapes and dimensions are exaggerated for clarity, and the same reference numerals are used throughout to designate the same or similar components.

FIG. 2 is a side sectional view illustrating an LED package 100 according to an embodiment of the present invention. Referring to FIG. 2, the LED package 100 includes a package body 101 having a recessed part 109 and an LED chip 107 mounted on the package body 101. The package body 101 may be made of polymer or ceramics. Lead electrodes 103 and 104 are disposed on a floor surface of the recessed part 109 and a sidewall surface of the recessed part 109 forms a reflecting surface 105. The LED chip 107 is mounted on a floor surface of the recessed part 109 so as to be connected to the lead electrodes 103 and 104.

As shown in FIG. 2, a lens structure 108 and 110 is attached on an upper surface of the package body 101, apart from the LED chip 107. The lens structure 108 and 110 includes a lens 108 and a phosphor-containing resin film 110 formed on a bottom surface of the lens 108. This resin film 110 has phosphor dispersed therein, thereby converting the wavelength of light emitted from the LED chip 107. For example, the resin film 110 may be made of silicone resin or epoxy resin with yellow phosphor such as YAG:Ce dispersed therein. Together with the yellow phosphor, a blue LED chip can be used to realize a white LED package. As described later, the phosphor-containing resin film 110 may be formed via spin coating or bonding.

According to this embodiment, the phosphor-containing resin film 110 is disposed apart from the LED chip 107 to curb deterioration of the phosphors by the heat discharged from the LED chip 107, thereby preventing degradation of light extraction efficiency due to heat. In addition, as the phosphor is dispersed in the resin film 110, apart from the LED chip 107, the difference between the paths of light passing through the phosphor is decreased, thereby ensuring uniform light emission characteristics.

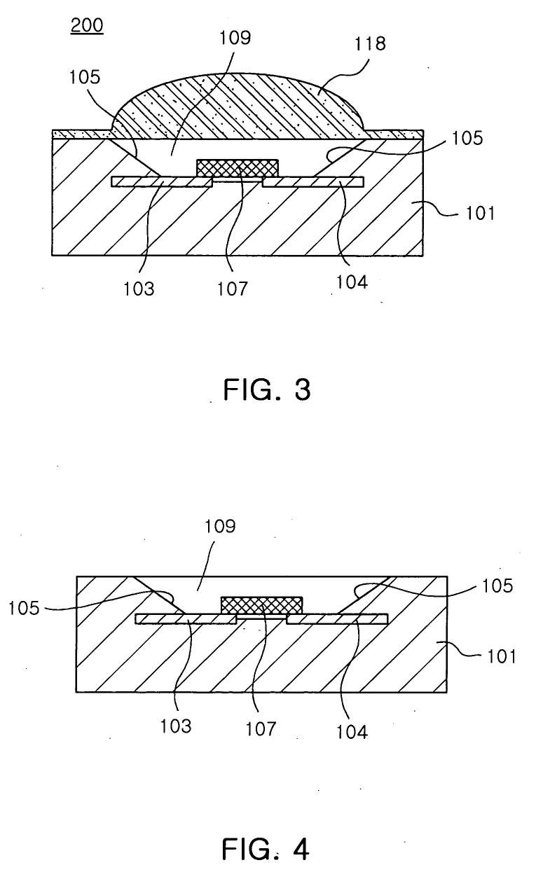

FIG. 3 is a side sectional view illustrating an LED package according to another embodiment of the present invention. Referring to FIG. 3, the LED package 200 of this embodiment adopts a lens 118 with phosphor dispersed therein instead of a phosphor-containing resin film. That is, the phosphor is dispersed in the lens 118 itself so that emitted light goes through wavelength conversion as it passes through the lens. Therefore, the lens 118 itself is a lens structure including the phosphor. Other constituents besides the lens structure are identical to those in the previous embodiment. Such a lens 118 may be fabricated using a lens material containing phosphor already dispersed therein.

Similar to the previous embodiment, the phosphor is dispersed in a location (the location of the lens) apart from the LED chip 107, preventing deterioration of the phosphor by the heat of the LED chip 107 and degradation of light extraction efficiency. In addition, with the phosphor disposed apart from the LED chip 107, the difference between the paths of light passing through the phosphor can be decreased to thereby ensure uniform light emission characteristics.

In the previously described embodiments, the recessed part 109 is left as an empty space, but may be filled with a light-transmitting resin such as a silicone resin. That is, the light-transmitting resin (without the phosphor dispersed therein) can be used to encapsulate the LED chip 107 mounted in the recessed part 109.

Now, manufacturing methods of the light emitting diode packages according to the embodiments of the invention will be explained.

FIGS. 4 to 7 are sectional views for illustrating the manufacturing method of the LED package 100 described in FIG. 2. As shown in FIG. 4, an LED chip 107 is mounted on a floor surface of a recessed part 109 of a package body 101 so as to be connected to lead electrodes 103 and 104 disposed on a floor surface of the recessed part 109.

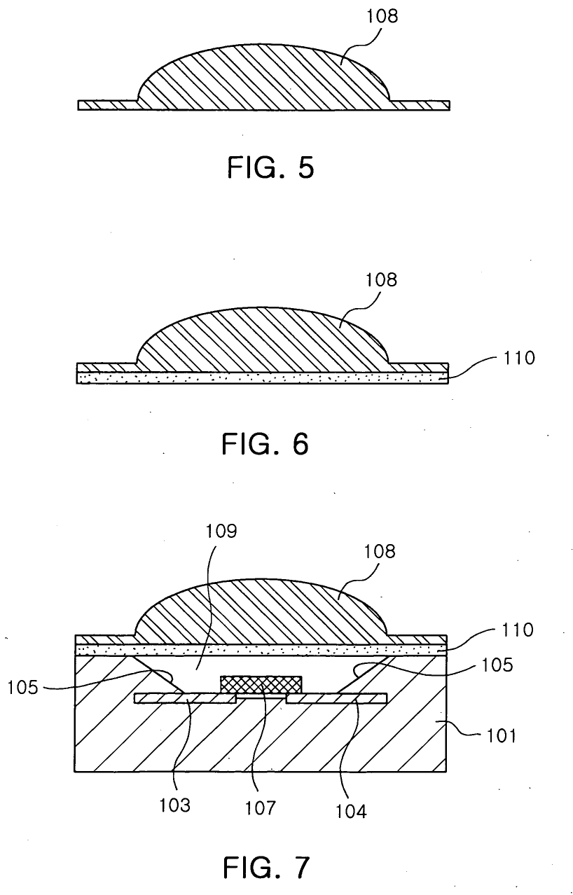

Thereafter, as shown in FIG. 5, a lens 108 is prepared. The lens 108 may be fabricated via various methods such as mechanical machining, using molds and so forth. Once the lens 108 is prepared, a phosphor-containing resin film 110 is formed on a bottom surface of the lens 108, as shown in FIG. 6. The phosphor-containing resin film 110 can easily be formed by spin-coating the resin with the phosphor dispersed therein on a bottom surface of the lens 108. As an alternative, a resin film with phosphor dispersed therein is fabricated first and then bonded onto a bottom surface of the lens 108. Thereby, a lens structure 108 and 110 shown in FIG. 6 is obtained.

Next, as shown in FIG. 7, the lens structure 108 and 110 is attached on an upper surface of the package body 101 using a suitable adhesive material. Thereby, an LED package having a phosphor-containing resin film 110 disposed apart from the LED chip 107, is obtained.

In this embodiment, the LED chip 107 is mounted on the package body 101 first and then the lens structure 108 and 110 is prepared. But, the steps of mounting the LED chip and preparing the lens structure 108 and 110 can be reversed in order. That is, the lens structure 108 and 110 may be prepared first, and then the LED chip 107 can be mounted on the package body 101. Also, the two steps can be conducted simultaneously.

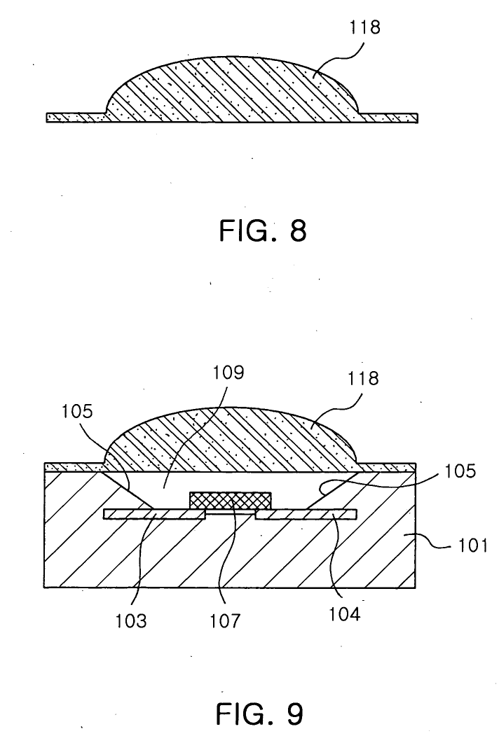

FIGS. 8 and 9 are sectional views illustrating the manufacturing method of the LED package according to another embodiment of the present invention. In this embodiment, as explained above with reference to FIG. 4, an LED chip 107 is mounted on a package body 101 having a recessed part 109. After or before the LED chip 107 is mounted, or simultaneous with the mounting of the LED chip 107, a lens 118 with phosphor dispersed therein is prepared as shown in FIG. 8. The lens 118 may be fabricated with a lens material with phosphor already dispersed therein. According to this embodiment, the lens 118 itself functions as a lens structure for converting the wavelength and the beam angle. Preferably, the phosphor is evenly dispersed throughout an entire area of the lens.

Thereafter, as shown in FIG. 9, the lens 118 is attached on an upper surface of the package body 101. Thereby, an LED package including phosphor disposed apart from the LED chip 107, is obtained.

In the above described manufacturing methods, the recessed part 109 is left as an empty space but after mounting the LED chip 107, a light-transmitting resin can be filled in the recessed part 109 to encapsulate the LED chip 107. Thereby, the LED chip 107 can be more safely protected from the external environment or impacts.

According to the present invention set forth above, phosphor is dispersed in at least a part of a lens structure disposed apart from an LED chip, thereby preventing deterioration of the phosphor by the heat discharged from the LED chip. This in turn improves light extraction efficiency. Furthermore, the phosphor is dispersed in a resin film or in a lens, apart from the LED chip, decreasing the difference in the paths of light passing through the phosphor, thereby ensuring uniform light emission characteristics.

While the present invention has been shown and described in connection with the preferred embodiments, it will be apparent to those skilled in the art that modifications and variations can be made without departing from the spirit and scope of the invention as defined by the appended claims.

What is claimed is:

1. A light emitting diode package comprising:
a package body having a recessed part;
a light emitting diode chip mounted on a floor surface of the recessed part; and
a lens structure disposed apart from the light emitting diode chip and above the package body, the lens structure containing a phosphor dispersed in at least a part thereof.

2. The light emitting diode package according to claim 1, wherein the light emitting diode chip is a blue light emitting diode chip, and the phosphor is yellow phosphor.

3. The light emitting diode package according to claim 1, wherein the lens structure comprises a lens and a resin film formed on a bottom surface of the lens, the resin film containing the phosphor.

4. The light emitting diode package according to claim 1, wherein the lens structure comprises a lens containing the phosphor dispersed therein.

5. The light emitting diode package according to claim 4, wherein the phosphor is dispersed throughout an entire area of the lens.

6. The light emitting diode package according to claim 1, further comprising light-transmitting resin molded between the lens structure and the light emitting diode chip to encapsulate the light emitting diode chip.

7. A method of manufacturing a light emitting diode package, comprising steps of:
mounting a light emitting diode chip on a floor surface of a recessed part of a package body;
preparing a lens structure containing phosphor dispersed in at least a part thereof; and
attaching the lens structure on an upper surface of the package body, apart from the light emitting diode chip.

8. The method according to claim 7, further comprising encapsulating the light emitting diode chip with a light-transmitting resin after the mounting step.

9. The method according to claim 7, wherein the preparing step comprises fabricating a lens and forming a phosphor-containing resin film on a bottom surface of the lens.

10. The method according to claim 9, wherein the step of forming the phosphor-containing resin film comprises spin coating resin with the phosphor dispersed therein on a bottom surface of the lens.

11. The method according to claim 9, wherein the step of forming the phosphor-containing resin film comprises bonding a resin film with the phosphor dispersed therein on a bottom surface of the lens.

12. The method according to claim 7, wherein the step of preparing the lens structure comprises dispersing the phosphor in a lens material and forming a lens using the lens material.
